(19) United States
(12) Patent Application Publication
(10) Pub. No.: US 2024/0105641 A1
(43) Pub. Date: Mar. 28, 2024

(54) CORRECTION OF GLOBAL CURVATURE DURING STRESS MANAGEMENT

(71) Applicant: Applied Materials, Inc., Santa Clara, CA (US)

(72) Inventor: Pradeep K. SUBRAHMANYAN, Santa Clara, CA (US)

(21) Appl. No.: 18/242,812

(22) Filed: Sep. 6, 2023

Related U.S. Application Data
(60) Provisional application No. 63/410,978, filed on Sep. 28, 2022.

(51) Int. Cl. H01L 23/00; H01L 21/02; H01L 21/3115

(52) U.S. Cl. CPC H01L 23/562; H01L 21/0217; H01L 21/31155

(57) ABSTRACT

Embodiments of the disclosure relate to techniques and apparatus for reducing out-of-plane distortion (OPD) in a substrate, as well as control of the effects of OPD and the effects that the modifications made to the substrate to correct for the OPD have on subsequent substrate processing operations performed on the substrate. The present embodiments employ novel techniques to reduce the OPD in a substrate without adding or modifying portions of the substrate that will create issues in subsequent substrate fabrication processes.

### CROSS-REFERENCE TO RELATED APPLICATIONS

This application claims priority to U.S. Provisional Application Ser. No. 63/410,978 filed Sep. 28, 2022, which is herein incorporated by reference in its entirety.

### BACKGROUND

### Field

The present disclosure generally relates to stress control in substrates, and more particularly to stress compensation to reduce out-of-plane distortion in substrates.

### Description of the Related Art

Memory devices are an essential component in digital electronic devices that are being developed today. With the increase in technology today, there is a need for increased memory capacity in most electronic devices. At the same time there is also a need for smaller memory devices to meet the market place's desire to create smaller electronic devices in which the memory device is positioned within.

In recent years, conventional (2D) NAND memory devices have run into a number of challenges, including voltage drop related issues (e.g., running out of electrons in the current carrying elements due to the ever scaling of the cell size), retention loss and overall reliability. To address these challenges encountered in scaling planar (2D) NAND memory devices to achieve higher densities at a lower cost per bit, ultra-high density, three-dimensional (3D) stacked memory structures have been introduced. Such 3D memory structures are sometimes referred to as having a Bit Cost Scalable (BiCS) architecture, and include strings of vertically integrated memory cells. Typically, the vertically aligned memory cells are formed from an array of alternating conductor and insulator layers, where the conductive layers correspond to the word lines of the memory structure.

As the number of vertically stacked memory cells in 3D NAND devices increases (e.g., as chip densities increase), the stress created within the stacked memory cells increases, which increase the substrate bow and introduces numerous performance issues. Local variations in the material composition in the vertically stacked memory cells may induce stress that deforms or warps the semiconductor substrate upon which structures are formed. Substrate flatness or bow has a very large influence on semiconductor device fabrication because of the impact it can have on the ability of photolithograph systems to effectively form device patterns on a surface of the substrate. Even moderate changes in surface topography within the area of the photolithograph exposure can alter the device feature patterns and, ultimately, lead to potential die yield loss. For accurate formation device patterns, it is important to form a pattern on a substrate while the substrate remains relatively flat or planar. Substrate bow is also important for other related fabrication processes, since deformation or warping of a substrate may also cause difficulty in subsequent processing steps that may include chip bonding or packaging.

One general concern for fabricating such devices and structures on a substrate is the development of in-plane distortion (IPD), which affects the overlay of a layer with respect to an underlying reference layer. IPD is a complex quantity affected by both the out-of-plane distortion (OPD) of the substrate and the alignment scheme employed in photolithography. OPD is the fundamental substrate quantity and the signature of the residual OPD formed in substrate due to stress is critical to the achievable overlay. For example, a type of OPD often encountered is a global substrate curvature that may develop at many instances of processing due to stress buildup in the substrate as a result of processing operations.

Therefore, there is a need for an improved memory device structure and method of forming the same that solves the problems described above.

### SUMMARY

Embodiments of the present disclosure provide a semiconductor device containing substrate. The semiconductor device containing substrate includes a plurality of semiconductor device layers formed on a front-side surface of a substrate, wherein the semiconductor device layers include at least one layer that includes a compressive or tensile stress that causes an out-of-plane-distortion in the substrate, and a distortion correction structure that is formed on a backside surface of the substrate, and includes a distortion correction layer that includes a first material that has a compressive or tensile stress as-deposited on the backside surface and has a thickness, and implanted ions that is distributed uniformly across a backside surface of the first material disposed across the backside surface of the substrate, wherein the thickness and compressive or tensile stress formed in the as-deposited first material is unable to compensate for all of the out-of-plane-distortion formed in the substrate, the implanted ions include a uniform dose of an implanted ion that was provided at a first ion energy, and the combination of the as-deposited first material and the addition of the implanted ions within the first material is configure to correct the out-of-plane-distortion formed in the substrate.

Embodiments of the present disclosure also provide a method of forming a three-dimensional memory device. The method includes measuring an out-of-plane-distortion formed in a substrate that includes a plurality of semiconductor device layers formed on a front-side surface of the substrate, determining at least one distortion correction parameter that is used to form a distortion correction structure that is formed on a backside surface of the substrate, forming a distortion correction layer of the distortion correction structure on the backside surface of the substrate, wherein the distortion correction layer includes a first material that has a compressive or tensile stress as-deposited on the backside surface and has a thickness, and performing an ion implant process to implant ions uniformly across a backside surface of the first material deposited on the backside surface of the substrate, wherein the thickness and compressive or tensile stress formed in the as-deposited first material is unable to compensate for all of the out-of-plane-distortion formed in the substrate, the implanted ions include a uniform dose of an implanted ion that was provided at a first ion energy, and the combination of the as-deposited first material and the addition of the implanted ions within the first material is configure to correct the out-of-plane-distortion formed in the substrate.

Embodiments of the present disclosure further provide a method of forming a distortion correction structure. The method includes depositing a distortion correction layer on a backside surface of a substrate including a plurality of semiconductor device layers on a front-side of the substrate, wherein at least one of the plurality of semiconductor device layers has a compressive or tensile stress that causes an out-of-plane-distortion in the substrate, and performing an ion implant process to expose the as-deposited distortion correction layer to a uniform dose of implanted ions.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 illustrates a substrate that includes an out-of-plane-distortion.

FIG. 2 illustrates the substrate after a conventional stress compensation layer has been added to a rear surface of the substrate shown in FIG. 1.

FIG. 3 illustrates a method of forming a distortion correction structure, according to one or more of the embodiments described herein.

FIGS. 4 and 5 illustrate portions of a distortion correction structure forming process that has been performed on the substrate shown in FIG. 1, according to one or more of the embodiments described herein.

FIG. 6 is a graph that illustrates the effect of providing increasing amounts of a uniform implant dose to the distortion correction layer of the distortion correction structure, according to one or more of the embodiments described herein.

FIGS. 7-9 illustrate the effect that different uniform implant dose levels have on the out-of-plane-distortion, according to one or more of the embodiments described herein.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

In the following description, details are set forth by way of example to facilitate an understanding of the disclosed subject matter. It should be apparent to a person of ordinary skill in the field, however, that the disclosed implementations are exemplary and not exhaustive of all possible implementations. Thus, it should be understood that reference to the described examples is not intended to limit the scope of the disclosure. Any alterations and further modifications to the described devices, instruments, methods, and any further application of the principles of the present disclosure are fully contemplated as would normally occur to one skilled in the art to which the disclosure relates. In particular, it is fully contemplated that the features, components, and/or steps described with respect to one implementation may be combined with the features, components, and/or steps described with respect to other implementations of the present disclosure. As used herein, the term “about” may refer to a +/−10% variation from the nominal value. It is to be understood that such a variation can be included in any value provided herein.

The embodiments described herein relate to techniques and apparatus for reducing out-of-plane distortion (OPD) in a substrate, as well as control of the effects of OPD and the effects that the modifications made to the substrate to correct for the OPD have on subsequent substrate processing operations performed on the substrate. The present embodiments employ novel techniques to reduce the OPD in a substrate without adding or modifying portions of the substrate that will create issues in subsequent substrate fabrication processes.

As noted above, in one application example, as the number of vertically stacked memory cells in 3D NAND devices increases (e.g., as chip densities increase), the stress created within the stacked memory cells increases, which increase the OPD of the substrate, and thus increases what is often referred to as “wafer bow” or “substrate bow”. To compensate for a global substrate bow, or a bow created across the whole substrate surface, it has been common practice to deposit a stress compensation layer to a desired thickness on a surface of the substrate such that an intrinsic stress and extrinsic stress within the deposited stress compensation layer will tend to counteract the global substrate bow created by the prior substrate processing steps. Thus, as the global substrate bow increases the thicker the deposited stress compensation layer needs to be to counteract the larger substrate bow. It is common for metal contamination reasons for the deposited stress compensation layer to include a dielectric film layer, such as a silicon oxide (SiOₓ), silicon nitride (SiN), carbon, or a combination thereof.

However, during the fabrication of most semiconductor devices it is common for the substrates to be processed using one or more plasma processes, such as a physical vapor deposition (PVD) process, plasma enhanced chemical vapor deposition (PECVD) process, reactive ion etching (RIE) process, plasma-enhanced atomic layer deposition (PEALD) process or other similar processing technics multiple times as the device layers are formed on a substrate. During most plasma processes, in an effort to assure good temperature control, it is desirable to electrostatically chuck the substrate to a surface of a substrate support. The act of electrostatically chucking a substrate to a surface of a substrate support causes charges to migrate to and build up in the lower surface of the substrate during processing. The built up charge needs to be discharged before the substrate can be removed from the surface of the substrate support, which is often referred to as a process of de-chucking the substrate. However, as the thickness of the stress compensation layer that is deposited on the backside of the substrate increases the ability for all of the built up charge in the back surface of the substrate to be discharged becomes much harder to do completely or harder to do within a reasonable period of time. The inability to discharge the built up charge also greatly increases the chance of the substrate being damaged or broken as it is being separated from the substrate support surface by use of a substrate lifting mechanism, which often leads to the generation of particles and chamber downtime to remove a damaged or broken substrate.

### Stress Compensation Process

In an effort to eliminate or minimize the complex distortion shape formed in a deformed substrate, a distortion correction structure and process sequence to form the same has been developed and is disclosed herein.

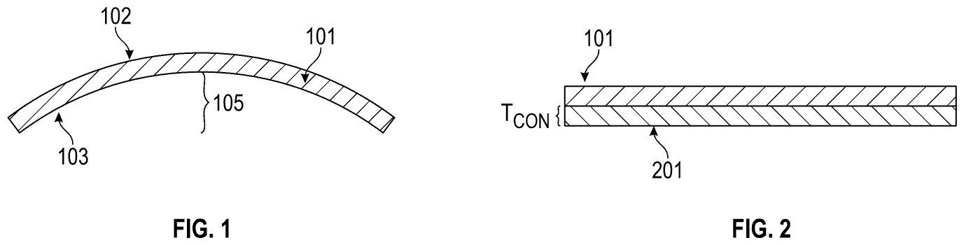

FIG. 1 illustrates is a side cross-section view of a substrate that has a significant global substrate bow created by a large OPD. The amount of deflection created by the OPD can be measured at the center or neutral axis of the substrate 101. In one example, the substrate 101 includes semiconductor device layers formed on a front-side surface 102 of the substrate 101 that are used to form 3D memory devices. At least one layer of the semiconductor device layers has a compressive or tensile stress that causes an out-of-plane-distortion (OPD) in the substrate 101.

FIG. 2 is a side cross-sectional view of a substrate 101 after a conventional stress compensation layer 201 has been formed on a backside surface 103 of the substrate 101. The conventional stress compensation layer 201 includes a thickness T_{CON} and is typically formed from a dielectric material. However, as noted above, due to the large required thickness of the conventional stress compensation layer 201 the properties of the dielectric film can create significant problems in a number of subsequent processes performed on the substrates. In one example, it has been found that silicon nitride (SiN) containing conventional stress compensation layers that have thickness greater than 5,000 angstroms (Å), for example, deposited on the backside surface 103 of the substrate 101 have an undesirably high breakage rate when used in typical processes that utilize an electrostatic chuck. In some cases, that conventional stress compensation layers may have a thickness of about 1 μm per about 5 μm to about 8 μm of warp or bow, as discussed in U.S. Patent Application Publication Number 20170178891A1.

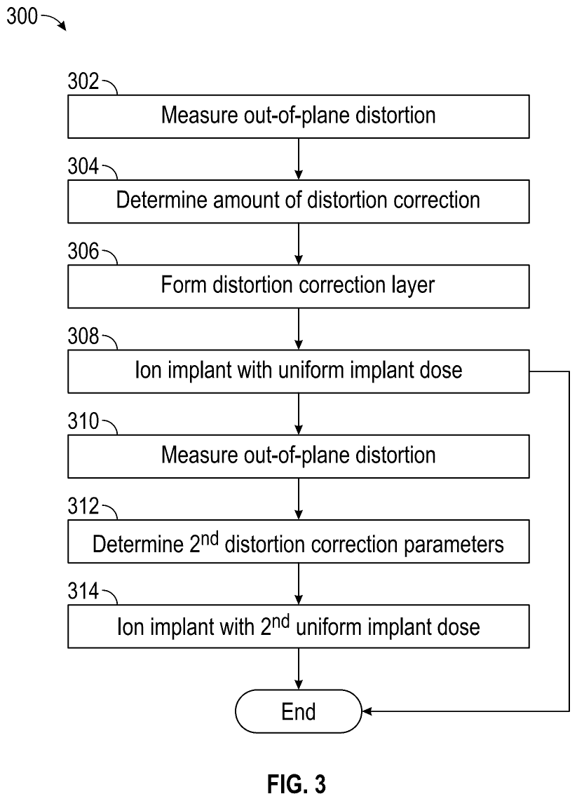

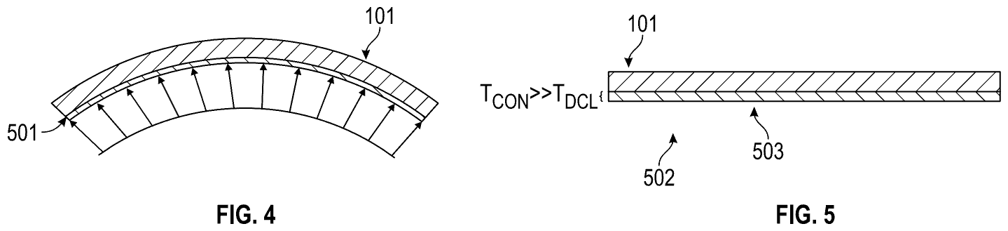

FIG. 3 illustrates a method 300 for use in the formation of a distortion correction structure 502 that is used to compensate for the OPD found in the substrate 101, according to one or more of the embodiments described herein. FIGS. 4 and 5 are schematic side cross-sectional views of a substrate 101 during different stages of the distortion correction structure 502 formation process illustrated in FIG. 3, according to one or more of the embodiments described herein. In general, the distortion correction structure 502 formation process includes the deposition of a distortion correction layer 501 that has a thickness T_{DCL}, and then expose the deposited distortion correction layer 501 formed on the backside surface 103 of the substrate 101 to a uniform implant dose to correct the OPD in the substrate 101.

The method 300 begins at activity 302, where the OPD of a substrate 101 is measured by use of conventional substrate bow measurement techniques. Conventional measurement techniques can be performed by use of a WaferSight™ tool available from KLA of Milpitas, California, a Metrology System from MTI Instruments of Albany, NY or other similar substrate bow measurement tool.

At activity 304, a system controller (not shown) within one or more distortion correction structure processing tools determines the desired amount of distortion correction that is required by one or more of the various parts of a distortion correction structure 502 that is to be formed on the backside surface of the substrate 101. The determined amount of correction that is required is based on the data collected during activity 302. The system controller includes a programmable central processing unit (CPU) which is operable with a memory (e.g., non-volatile memory) and support circuits. The support circuits are conventionally coupled to the CPU and comprise cache, clock circuits, input/output subsystems, and the like, and combinations thereof coupled to the various components within one or more distortion correction structure processing tools, to facilitate control thereof. The CPU is one of any form of general purpose computer processor used in an industrial setting for controlling various components and sub-processors of the processing system. Typically, the memory is in the form of a non-transitory computer-readable storage media containing instructions (e.g., non-volatile memory), which when executed by the CPU, facilitates the operation of the one or more distortion correction structure processing tools. The computer instructions in the memory are in the form of a program product such as a program that implements the one or more portions of the methods of the present disclosure.

At activity 306, the as-deposited distortion correction layer 501 is formed on the backside surface of the substrate 101. The process of forming the as-deposited distortion correction layer 501 can include depositing a dielectric containing layer on the backside surface 103 by use of a chemical vapor deposition (CVD) process, a physical vapor deposition process (PVD), an atomic layer deposition (ALD) process or other useful deposition process. The thickness T_{DCL} of the as-deposited distortion correction layer 501 is selected by use of the prior activities such that it is less than the thickness required to fully compensate for the OPD of the substrate 101, and also have a thickness that will assure that the distortion correction layer 501 will not create problems in any subsequent manufacturing processes. In one example, the as-deposited distortion correction layer 501 may include a silicon nitride (Si₃N₄) containing layer that is formed by a PVD or a CVD process. In some embodiments, the system controller determines the required thickness T_{DCL} of the as-deposited distortion correction layer 501 based on the data collected during activity 302. The thickness T_{DCL} can be selected based on aspects of the implant dose that is to be provided during activity 308, and thus the thickness T_{DCL} of the as-deposited distortion correction layer 501 is adjusted based on implant dosing parameters used during activity 308. In some cases, it is desirable to set the thickness of the as-deposited distortion correction layer 501 to be thick enough to assure that the implanted ions provided during the ion implant process performed during activity 308 does not cause the implanted ions to be implanted into the backside of the substrate 101. In some non-limiting examples, the as-deposited distortion correction layer 501 is silicon nitride (SiₓN_{y}) film layer that has a thickness T_{DCL} that is less than 4,000 Å, such as less than 2,000 Å, or between 1,000 Å and 2,000 Å.

At activity 308, an ion implant process is performed, in which the as-deposited distortion correction layer 501 is exposed to a dose of implanted ions (also referred to as “implant dose”) so that the modified as-deposited distortion correction layer 501, which is referred to herein as the distortion correction layer 503, will correct for the OPD, as shown in FIG. 5. In some embodiments, the dose of implanted ions includes a spatially uniform dose of ions. Suitable implanted ions provided from an ion beam may include any ion species capable of inducing a stress change after being implanted at a suitable ion energy, including ions such as argon (Ar), phosphorous (P), silicon (Si), carbon (C), boron (B), nitrogen (N₂), krypton (Kr), indium (In), or fluorine (BF₂), according to some non-limiting embodiments, with ion energy being tailored according to the exact ion species used. The dose of implanted ions is applied to the as-deposited distortion correction layer 501 by use of an ion implant energy source, in order to correct OPD, and thus to reduce or minimize in-plane-distortion (IPD) that affects device fabrication and other device patterning procedures. Non-limiting examples of ion implant energy sources include an ion beam that is scannable with respect to backside surface 103 of the substrate 101. In various embodiments, an ion implant energy source may transfer a dose into a substrate that involves a uniform, direct write, process. In this context, a ‘direct write’ process, including a direct write implant process, may refer to a process that employs relative movement of an ion beam or other beam that is used to produce a uniform dose across a substrate surface. In some embodiments, a direct write process using an ion implant energy source may involve an exposure to electrons, such as an electron beam, or photons, such as a laser beam, may be used to globally adjust stress in the as-deposited distortion correction layer 501 to adjust the curvature of a substrate, and thus the substrate's OPD. In some embodiments of activity 308, the system controller determines the required ion implant process parameters, such ion energy (keV), dose amount (atoms/cm²), and/or even ion species, based on the data collected during activity 302 and the thickness of the as-deposited distortion correction layer 501. In some embodiments, the method 300 is completed after performing activity 308 so that the substrate 101 can then be transferred on to one or more subsequent processing steps, such additional 3D memory device (e.g., 3D NAND device) processing steps. In one non-limiting example, the ion implant process includes implanting argon (Ar) ions at a constant energy, such as 65 keV into a silicon nitride (SiₓN_{y}) as-deposited distortion correction layer that has a thickness of about 1,300 Å and a dose of between 1×10¹² and 1×10¹⁶ atoms/cm². In another non-limiting example, the ion implant process includes implanting argon (Ar) ions at a constant energy, such as 70 keV into a silicon nitride (SiₓN_{y}) as-deposited distortion correction layer that has a thickness of about 2,000 Å to correct an OPD of about 300 μm.

However, in some embodiments of method 300, activities 310-314 are additionally performed to further adjust the OPD found in the substrate 101 after activities steps 302-308 were performed. At activity 310, after performing activities 302-308, the OPD of the substrate 101 is measured again to determine if further OPD correction is necessary. At activity 312, the system controller (not shown) determines a second desired amount of distortion correction that is required to correct the OPD found in the substrate 101. The determined second amount of distortion correction is based on the data collected during activity 310. At activity 314, an ion implant process is performed, where a second uniform dose of implanted ions are computed based on activities 310 and 312, and the distortion correction layer 503 formed during activity 308 is then exposed to a second uniform dose of an implanted ion so that the modified distortion correction layer 503 will correct for the remaining OPD.

In some other embodiments of method 300, during activity 308, the dose of implanted ions are computed, but an ion implant process is not performed during activity 308. In this case, during activity 314, an ion implant process is performed where the ion implant dose includes the delivery of a combined implant dose, which includes the ion implant dose computed during activity 308 and also the second implant dose determined during activity 314. Thus, at activity 314, the system controller determines the required ion implant process parameters for the delivery of the combined implant dose, such ion energy (keV), dose amount (atoms/cm²), and/or even ion species, based on the data collected during activities 302 and 310, and the thickness of the as-deposited distortion correction layer.

### EXAMPLES

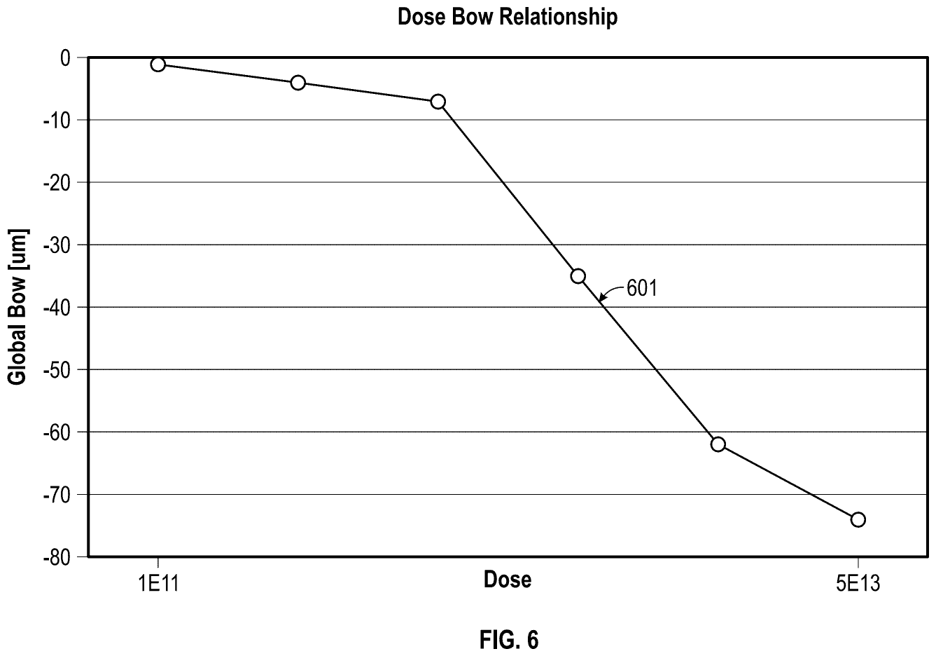

FIG. 6 is a graph that illustrates the effect of providing increasing amounts of a uniform implant dose to the distortion correction layer of the distortion correction structure. The graph was created using a fixed ion energy level that was applied across the whole backside surface of the substrate 101. It can be seen that global substrate bow 601 reduces as a dose of implanted ion increases.

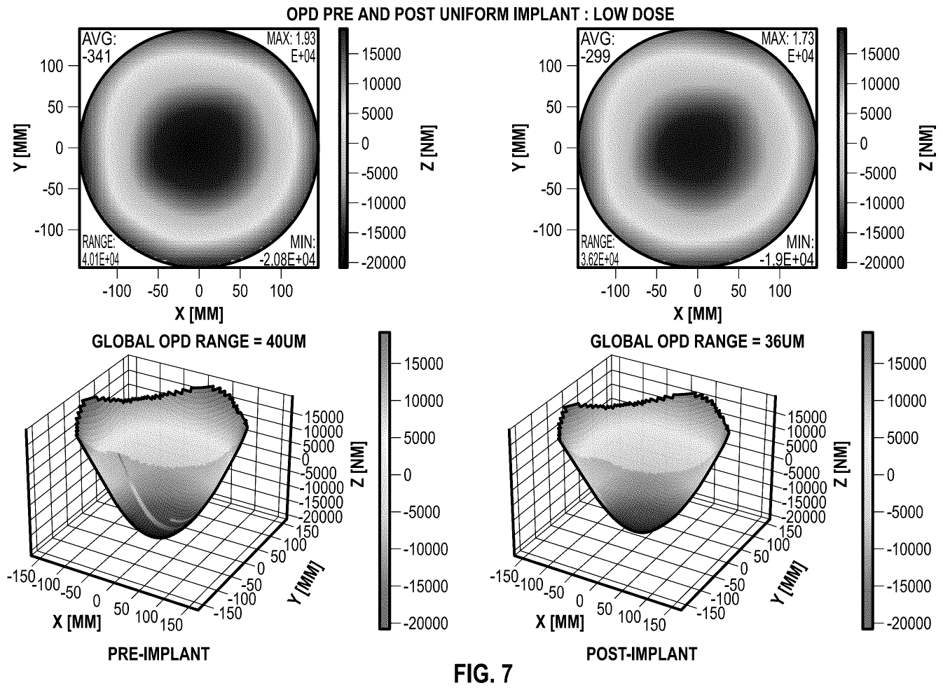

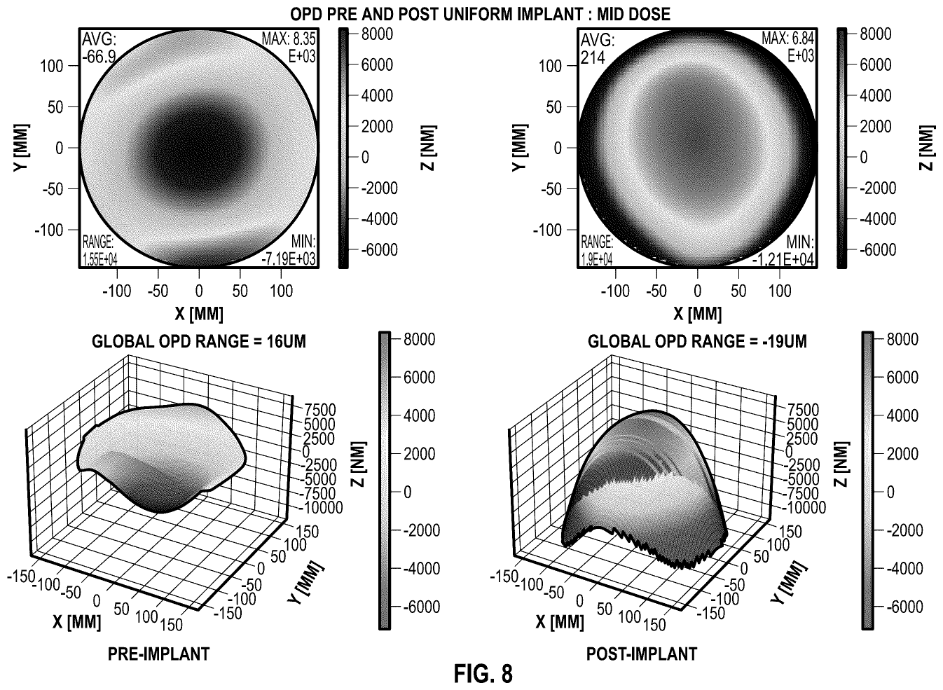

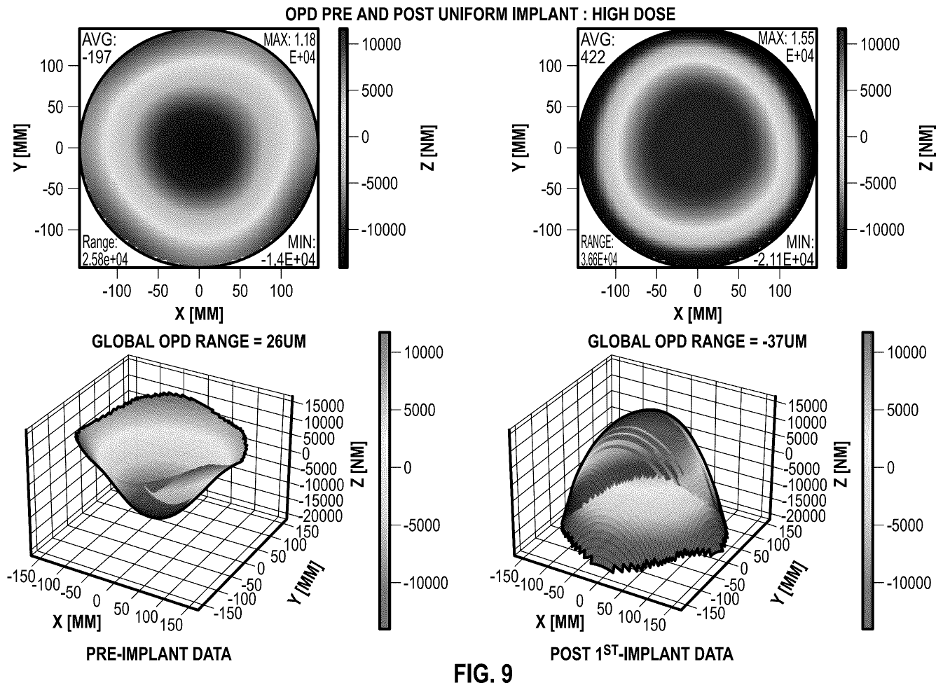

FIGS. 7-9 illustrate the effect that different uniform implant dose levels have on the out-of-plane-distortion by use of a distortion correction structure that includes a silicon nitride layer. FIG. 7 illustrates OPD data of an example substrate before and after ion implant with a low-uniform implant dose. FIG. 8 illustrates OPD data of an example substrate before and after ion implant with a mid-uniform implant dose. FIG. 9 illustrates an example of OPD data of a substrate before and after an ion implant process with a high-uniform implant dose. In the X-Y plot, OPD data is illustrated by a color, where red signifies the largest amplitude and dark blue signifies lowest amplitude. As shown in FIG. 7, substrate bow is slightly corrected (e.g., global substrate bow of 40 μm is corrected to 36 μm) at a low uniform implant dose. As shown in FIGS. 8 and 9, substrate bow is over corrected (e.g., global substrate bow of 16 μm and 26 μm are corrected to −19 μm and −37 μm, respectively) at a mid-uniform implant dose and a high-uniform implant dose.

Applications of the disclosure provided herein can be used during the formation of 2D NAND, 3D NAND, 2D DRAM, 3D DRAM and logic devices. Applications of the disclosure provided herein can also be used in various device packaging applications, such as hybrid wafer bonding and other similar packaging processes.

While the foregoing is directed to embodiments of the present disclosure, other and further embodiments of the disclosure may be devised without departing from the basic scope thereof, and the scope thereof is determined by the claims that follow.

We claim:

1. A semiconductor device containing substrate, comprising:
a plurality of semiconductor device layers formed on a front-side surface of a substrate, wherein the semiconductor device layers comprise at least one layer that includes a compressive or tensile stress that causes an out-of-plane-distortion in the substrate; and
a distortion correction structure that is formed on a backside surface of the substrate, and comprises a distortion correction layer that comprises:
a first material that has a compressive or tensile stress as-deposited on the backside surface and has a thickness; and
implanted ions that is distributed uniformly across a backside surface of the first material disposed across the backside surface of the substrate,
wherein
the thickness and compressive or tensile stress formed in the as-deposited first material is unable to compensate for all of the out-of-plane-distortion formed in the substrate,
the implanted ions include a uniform dose of an implanted ion that was provided at a first ion energy, and
the combination of the as-deposited first material and the addition of the implanted ions within the first material is configure to correct the out-of-plane-distortion formed in the substrate.

2. The substrate of claim 1, wherein the thickness of the as-deposited first material and parameters of an ion implant process used to implant ions are selected so that the implanted ions are not implanted into the backside surface of the substrate.

3. The substrate of claim 2, wherein the implanted ions comprise argon (Ar), phosphorous (P), silicon (Si), or carbon (C).

4. The substrate of claim 1, wherein the plurality of semiconductor device layers are configured to form at least a portion of a 3D memory device.

5. A method of forming a three-dimensional memory device, comprising:
measuring an out-of-plane-distortion formed in a substrate that comprises a plurality of semiconductor device layers formed on a front-side surface of the substrate;
determining at least one distortion correction parameter that is used to form a distortion correction structure that is formed on a backside surface of the substrate;
forming a distortion correction layer of the distortion correction structure on the backside surface of the substrate, wherein the distortion correction layer comprises a first material that has a compressive or tensile stress as-deposited on the backside surface and has a thickness; and
performing an ion implant process to implant ions uniformly across a backside surface of the first material deposited on the backside surface of the substrate, wherein
the thickness and compressive or tensile stress formed in the as-deposited first material is unable to compensate for all of the out-of-plane-distortion formed in the substrate,
the implanted ions include a uniform dose of an implanted ion that was provided at a first ion energy, and
the combination of the as-deposited first material and the addition of the implanted ions within the first material is configure to correct the out-of-plane-distortion formed in the substrate.

6. The method of claim 5, wherein the thickness of the as-deposited first material and parameters of the ion implant process used to implant the implanted ions are selected so that the implanted ions are not implanted into the backside surface of the substrate.

7. The method of claim 6, wherein implanted ion comprises argon (Ar), phosphorous (P), silicon (Si), or carbon (C).

8. The method of claim 7, wherein the plurality of semiconductor device layers are configured to form at least a portion of a 3D memory device.

9. The method of claim 5, wherein the at least one distortion correction parameter comprises at least one of the thickness of the as-deposited first material, ion energy, dose amount, and ion species required during the ion implant process.

10. The method of claim 5, wherein the determining the at least one distortion correction parameter is performed by a system controller after receiving information relating to the measurement of the out-of-plane-distortion formed in the substrate.

11. The method of claim 10, wherein the system controller is further configured to control the thickness of the as-deposited first material, ion energy, dose amount, and ion species during the ion implant process after determining the at least one distortion correction parameter.

12. A method of forming a distortion correction structure, comprising:
depositing a distortion correction layer on a backside surface of a substrate comprising a plurality of semiconductor device layers on a front-side of the substrate, wherein at least one of the plurality of semiconductor device layers has a compressive or tensile stress that causes an out-of-plane-distortion in the substrate; and
performing an ion implant process to expose the as-deposited distortion correction layer to a uniform dose of implanted ions.

13. The method of claim 12, wherein the distortion correction layer comprises a silicon nitride (Si₃N₄) containing layer.

14. The method of claim 12, wherein the distortion correction layer has thickness of between 1,000 Å and 2,000 Å.

15. The method of claim 12, wherein the implanted ions comprise phosphorous, boron, argon, nitrogen, krypton, indium, or boron fluorine.

16. The method of claim 12, wherein the ion implant process comprises implanting argon (Ar) ions at a constant energy of between 65 keV and 70 keV into the as-deposited distortion correction layer and a dose of between 1×10¹² and 1×10¹⁶ atoms/cm².

17. The method of claim 12, further comprising:
prior to the depositing of the distortion correction layer,
measuring the out-of-plane-distortion in the substrate; and
determining at least one distortion correction parameter that is used to form the distortion correction layer.

18. The method of claim 17, wherein the at least one distortion correction parameter comprises at least one of thickness of the distortion correction layer, ion energy, dose amount, and ion species required during the ion implant process.

19. The method of claim 12, further comprising:
subsequent to the ion implant process,
measuring an out-of-plane-distortion found in the substrate; and
determining at least one distortion correction parameter that is used to form an additional distortion correction layer.

20. The method of claim 19, further comprising:
depositing the additional distortion correction layer on the backside surface of the substrate; and
performing an ion implant process to expose the as-deposited additional distortion correction layer to a uniform dose of implanted ions.
